(19) United States
(12) Patent Application Publication
(10) Pub. No.: US 2014/0131759 A1
(43) Pub. Date: May 15, 2014

(54) SEMICONDUCTOR LIGHT-EMITTING ELEMENT

(71) Applicant: SAMSUNG ELECTRONICS CO., LTD., Suwon-si, Gyeonggi-do (KR)

(72) Inventors: Jae Yoon Kim, Yongin-si (KP); Je Won Kim, Seoul (KR); Jin Bock Lee, Osan-si (KR); Seok Min Hwang, Haeundae-gu (KR); Hae Soo Ha, Suwon (KR); Su Yeol Lee, Seongnam-si (KR)

(73) Assignee: SAMSUNG ELECTRONICS CO., LTD., Suwon-si, Gyeonggi-do (KR)

(21) Appl. No.: 14/129,524

(22) PCT Filed: Jul. 29, 2011
(86) PCT No.: PCT/KR2011/005589

§ 371 Date: Dec. 26, 2013

(51) Int. Cl. H01L 33/38

(52) U.S. Cl. CPC H01L 33/387
USPC 257/99

(57) ABSTRACT

A semiconductor light emitting device includes an n-type semiconductor layer, an active layer and a p-type semiconductor layer formed in a first region corresponding to a partial region of an upper surface of the n-type semiconductor layer, an n-type electrode formed in a second region different from the first region on the upper surface of the n-type semiconductor layer, and having an n-type pad and first and second n-type fingers, and a p-type electrode formed on the p-type semiconductor layer, and having a p-type pad and a p-type finger, wherein the n-type semiconductor layer, the active layer, and the p-type semiconductor layer form a light emitting structure, and a region in which the n-type and p-type fingers intersect to overlap with each other is formed.

### BACKGROUND OF THE INVENTION

1. Field of the Invention

The present invention relates to a semiconductor light emitting device and, more particularly, to a semiconductor light emitting device having an electrode structure in which a loss of light due to electrodes is minimized and a current spreading effect (or a current dispersion effect) is improved.

2. Description of the Related Art

A semiconductor light emitting device is a semiconductor device capable of generating light of various colors according to electron hole recombination occurring at p and n type semiconductor junctions when current is applied thereto. Compared with a filament-based light emitting device, a semiconductor light emitting device has various advantages such as a long lifespan, low power consumption, excellent initial driving characteristics, and the like, and accordingly, demand for semiconductor light emitting devices has continued to grow. In particular, recently, a group III-nitride semiconductor capable of emitting short-wavelength blue light has come to prominence.

A nitride single crystal is formed on a particular growth substrate such as a sapphire or SiC substrate. However, the use of an insulating substrate such as sapphire greatly limits an arrangement of electrodes. Namely, in the related art nitride semiconductor light emitting device, electrodes are generally arranged in a horizontal direction, thus narrowing a current flow. A narrowed current flow may lead to an increase in an operating voltage Vf of a light emitting device, potentially degrading current efficiency and weakening electrostatic discharge (ESD). Thus, in order to allow current to be uniformly spread across a light emitting surface, there have been attempts to divide an n-type electrode and a p-type electrode into a pad and a finger and alternately dispose them, and the like. However, as the proportions of pads and fingers are increased to achieve a current spreading effect, the area occupied by electrodes in the light emitting surface is also increased to thereby cause a loss of light. This is because the increase in the electrode area leads to a reduction in the area of an active layer to result in a reduction in external light extraction efficiency. Thus, in the art, a scheme of obtaining an electrode structure by which excellent current spreading effect may be achieved, and a loss of light minimized, is required.

### SUMMARY OF THE INVENTION

An aspect of the present invention provides a semiconductor light emitting device having an electrode structure in which loss of light due to electrodes is minimized and a current dispersion effect is improved.

According to an aspect of the present invention, there is provided a semiconductor light emitting device including: an n-type semiconductor layer; an active layer and a p-type semiconductor layer formed in a first region corresponding to a partial region of an upper surface of the n-type semiconductor layer; an n-type electrode formed in a second region different from the first region on the upper surface of the n-type semiconductor layer, electrically connected to the n-type semiconductor layer, and having an n-type pad and first and second n-type fingers; and a p-type electrode formed on the p-type semiconductor layer, electrically connected to the p-type semiconductor layer, and having a p-type pad and a p-type finger, wherein the n-type semiconductor layer, the active layer, and the p-type semiconductor layer form a light emitting structure, and a region in which the n-type and p-type fingers intersect to overlap with each other is formed.

An insulating layer may be interposed between the n-type finger and the p-type finger in the region in which the n-type finger and the p-type finger overlap with each other.

The insulating layer may be formed in a region obtained by removing portions of the n-type semiconductor layer, the active layer, and the p-type semiconductor layer.

The insulating layer may be formed in a region obtained by removing portions of the n-type semiconductor layer, the active layer, the p-type semiconductor layer, and the p-type pad.

The semiconductor light emitting device may further include a transparent electrode formed between the p-type semiconductor layer and the p-type electrode.

The light emitting structure may have a rectangular light emitting surface when viewed from above the p-type semiconductor layer, and the n-type electrode and the p-type electrode may be disposed to have a symmetrical structure based on at least one of a horizontal line, a vertical line, and a diagonal line traversing the center of the light emitting surface.

The n-type finger may be formed to extend in two different directions from the n-type pad, and the portions extending in the two different directions meet.

The p-type finger may have a portion formed within a region defined by the n-type finger when viewed from above the light emitting structure.

The p-type finger may be formed to extend in two different directions from the p-type pad, and the portions extending in the two different directions meet.

The n-type finger may have a portion formed within a region defined by the p-type finger when viewed from above the light emitting structure.

The light emitting structure may have a rectangular light emitting surface when viewed from above the p-type semiconductor layer, and the n-type pad and the p-type pad are disposed in opposing corners of the light emitting surface.

The n-type finger and the p-type finger may extend from the n-type pad and the p-type pad toward the opposing corners of the light emitting surface, and may be bifurcated in two different directions, and the n-type finger and the p-type finger may intersect in the bifurcated regions.

The n-type finger may extend from the n-type pad toward an opposing corner of the light emitting surface and extend from a portion positioned at the center of the light emitting surface in two directions perpendicular thereto, and the p-type finger may extend from the p-type pad toward two corners in which the n-type pad and the p-type pad are not formed on the light emitting surface and may be bent toward the n-type pad to intersect the n-type finger.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a plan view schematically illustrating a semiconductor light emitting device according to an embodiment of the present invention;

FIG. 2 is a cross-sectional view taken along line A-A′ of the semiconductor light emitting device of FIG. 1, and FIG. 5 is a view illustrating a modification of the structure of FIG. 2;

FIG. 3 is a cross-sectional view taken along line B-B′ of the semiconductor light emitting device of FIG. 1, and FIG. 4 is a cross-sectional view taken along line C-C′ of the semiconductor light emitting device of FIG. 1; and

FIGS. 6 and 7 are plan views schematically showing a semiconductor light emitting device according to another embodiment of the present invention, respectively.

### DETAILED DESCRIPTION OF THE PREFERRED EMBODIMENT

Embodiments of the present invention will now be described in detail with reference to the accompanying drawings.

The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like components.

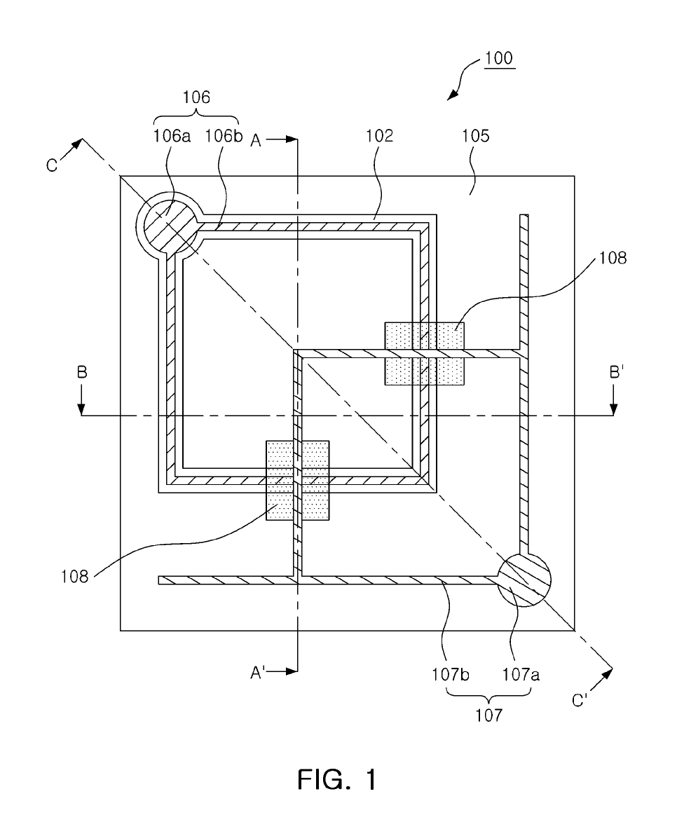

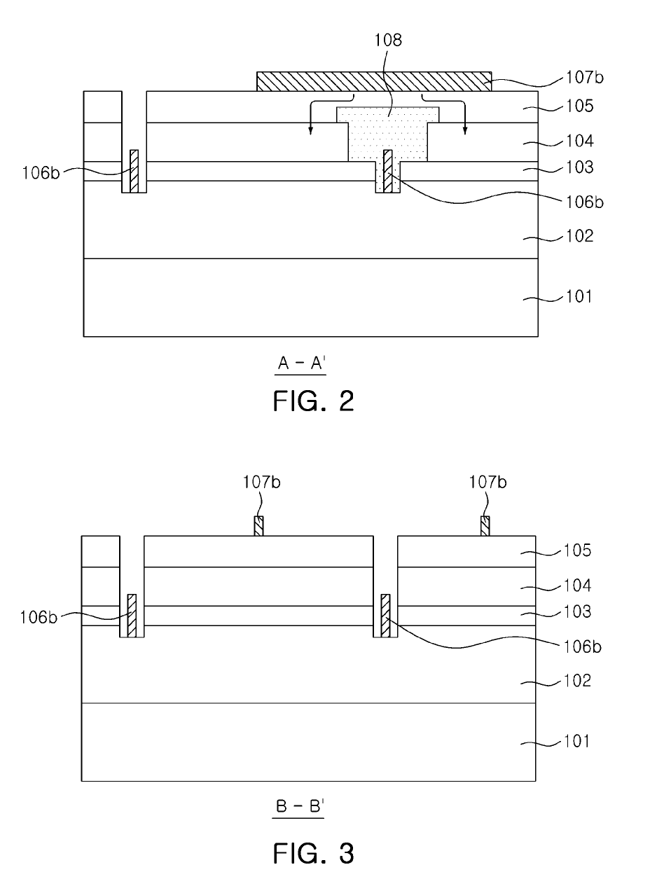

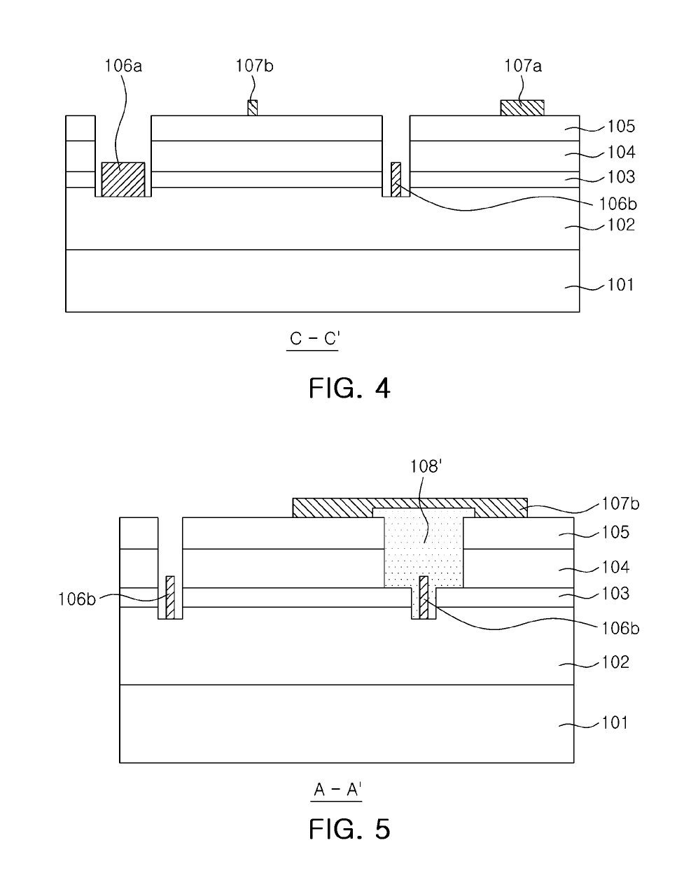

FIG. 1 is a plan view schematically illustrating a semiconductor light emitting device according to an embodiment of the present invention. FIG. 2 is a cross-sectional view taken along line A-A′ in the semiconductor light emitting device of FIG. 1, and FIG. 5 is a view illustrating a modification of the structure of FIG. 2. FIG. 3 is a cross-sectional view taken along line B-B′ in the semiconductor light emitting device of FIG. 1, and FIG. 4 is a cross-sectional view taken along line C-C′ in the semiconductor light emitting device of FIG. 1.

Referring to FIGS. 1 through 4, a semiconductor light emitting device 100 according to the present embodiment includes a light emitting structure formed on a substrate 101, and here, the light emitting structure includes an n-type semiconductor layer 102, an active layer 103, and a p-type semiconductor layer 104. In this case, although not shown, one or more buffer layers may be formed between the n-type semiconductor layer 102 and the substrate 101 in order to enhance crystallinity of the semiconductor layer formed thereon. A p-type electrode 107 is formed on the p-type semiconductor layer 104. The p-type electrode 107 includes a p-type pad 107a and a p-type finger 107b. In this case, a transparent electrode 105 that may perform an ohmic-contact function and a current dispersion function may be formed between the p-type electrode 107 and the p-type semiconductor layer 104, but the transparent electrode 105 is not an essential component of an embodiment of the present invention. The transparent electrode 105 may be made of a transparent conductive oxide such as indium tin oxide (ITO). An n-type electrode 106 is formed in a region in which the active layer 103 and the p-type semiconductor layer 104 are not formed. The n-type electrode 106 also includes an n-type pad 106a and an n-type finger 106b. Meanwhile, although not shown, an electrical insulating material may be applied to a surface of the light emitting structure to form a passivation structure.

The substrate 101 is provided to allow a single nitride semiconductor crystal to grow thereon, and a substrate made of material such as sapphire, silicon (Si), ZnO, GaAs, SiC, MgAl₂O₄, MgO, LiAlO₂, LiGaO₂, or GaN may be used as the substrate 101. In this case, sapphire is a crystal having Hexa-Rhombo R3c symmetry, of which lattice constants in c-axis and a-axis directions are 13.001 Å and 4.758 Å, respectively. A sapphire crystal has a C-plane (0001), an A-plane (1120), an R-plane (1102), and the like. In this case, a nitride thin film can be relatively easily formed on the C-plane of the sapphire crystal, and because sapphire crystal is stable at high temperatures, in particular, it is commonly used as a material for a growth substrate of a nitride semiconductor.

The n-type and p-type semiconductor layers 102 and 104 may be made of a nitride semiconductor, specifically, a material expressed by an empirical formula AlₓIn_{y}Ga(_{1-x-y})N (here, 0≦x≦1, 0≦y≦1, and 0≦x+y≦1). For example, the material may include GaN, AlGaN, and InGaN. The active layer 103 formed between the n-type and p-type semiconductor layers 102 and 104 emits light having a certain energy level according to the recombination of electrons and holes and may have a multi-quantum well (MQW) structure in which quantum well layers and quantum barrier layers are alternately laminated. Here, for example, an InGaN/GaN structure may be used. Meanwhile, the n-type and p-type semiconductor layers 102 and 104 and the active layer 103 may be formed by using a semiconductor layer growing process such as metal organic chemical vapor deposition (MOCVD), hydride vapor phase epitaxy (HVPE), molecular beam epitaxy (MBE), and the like, known in the art.

In the present embodiment, a current dispersion effect can be obtained and an electrode area occupying the interior of the light emitting surface is minimized by optimizing a disposition structure of the n-type and p-type electrodes 106 and 107. In detail, the n-type and p-type electrodes 106 and 107 are disposed to intersect each other. Here, the light emitting surface refers to a rectangular surface illustrated in FIG. 1, which corresponds to a surface obtained when the light emitting structure is viewed from above the p-type semiconductor layer 104. However, in an embodiment of the present invention, the light emitting surface is not necessarily required to have a perfect rectangular shape geometrically, and a shape slightly modified from a rectangular shape may be included in the range of the light emitting surface mentioned in the present embodiment. For example, a rectangular shape in which some of corners thereof are chamfered may also be included in the range of the light emitting surface.

The n-type electrode 106 includes the n-type pad 106a and the n-type finger 106b. The n-type pad 106a may have a width larger than that of the n-type finger 106b such that the n-type pad 106a can be connected to a conductive wire, or the like. In the present embodiment, the n-type pad 106a and the p-type pad 107a may be disposed in the opposing corners of the light emitting surface on the light emitting surface. The n-type finger 106b has a conductive line structure extending from the n-type pad 106a to allow a current to be uniformly injected into the entirety of the light emitting surface, and has a width narrower than that of the n-type pad 106a, but not necessarily. Similarly, the p-type pad 107a has a width greater than those of the p-type finger 107b. In the present embodiment, when viewed from above the light emitting structure, the p-type finger 107b is disposed to intersect the n-type finger 106b, and thus, as illustrated in FIG. 1, regions in which the n-type finger 106b and the p-type finger 107b overlap with each other are formed. Since the n-type finger 106b and the p-type finger 107b are disposed to intersect each other, the degree of freedom in designing the electrodes can be significantly enhanced, and accordingly, a proportion of the areas of the electrodes to the light emitting surface can be reduced. Without the use of the intersecting disposition structure, the lengths and occupation areas of the n-type finger 106b and the p-type finger 107b may be inevitably increased to form electrodes having a similar level of performance to those of the present embodiment. In addition, as described hereinafter, a current dispersion effect can be obtained by disposing an insulating layer 108 for preventing an occurrence of short-circuit between the n-type finger 106b and the p-type finger 107b.

In detail, the n-type finger 106b extends in two different directions from the n-type pad 106a, and the portions extending in the two different directions may be formed to meet each other. The p-type finger 107b may include a portion formed within a region defined by the n-type finger 106b. In this case, although not shown, the n-type finger 160b and the p-type finger 107b may have the mutually opposing shapes. Namely, the p-type finger 107b extends in two different directions from the p-type pad 107a and the portions extending in the two different directions may meet each other, and the n-type finger 106b may have a portion formed within the region defined by the p-type finger 107b. Such an electrode disposition cannot be implemented unless the p-type finger 106g and the p-type finger 107b intersect each other. Meanwhile, preferably, the n-type electrode 106 and the p-type electrode 107 are disposed to have a symmetrical structure based on at least one of a horizontal line, a vertical line, and a diagonal line traversing the center of the light emitting surface, but not necessarily. In the present embodiment, the n-type electrode 106 and the p-type electrode 107 are disposed to be symmetrical based on a diagonal line (corresponding to the line C-C′).

When the n-type finger 106b and the p-type finger 107b are disposed to intersect each other, an appropriate electrically insulating structure is required to be interposed in the region in which the n-type finger 106b and the p-type finger 107b overlap with each other. To this end, as illustrated in FIGS. 1 and 2, the insulating layer 108 is interposed between the n-type finger 106b and the p-type finger 107b in the region in which the n-type finger 106b and the p-type finger 107b overlap with each other. The insulating layer 108 is made of a material having electrical insulating properties, e.g., a silicon oxide or a silicon nitride, and may be formed in a region obtained by removing portions of the n-type semiconductor layer 102, the active layer 103, and the p-type semiconductor layer 104. In this case, when the light emitting structure is viewed from above, the insulating layer 108 may have a quadrangular shape, but the present invention is not limited thereto and the insulating layer 108 may be variably modified to have other shapes such as a polygonal shape, a circular shape, an oval shape, and the like. The insulating layer 108 may induce a current to flow (indicated by arrows in FIG. 2) in the lateral direction of the light emitting structure, as well as providing a short-circuit preventing function, contributing toward the enhancement of a current dispersion effect. Meanwhile, as shown in a modification of FIG. 5, an insulating layer 108′ may be formed in a region obtained by removing portions of the n-type semiconductor layer 102, the active layer 103, the p-type semiconductor layer 104, and even the p-type electrode 107, specifically, the p-type finger 107b, as necessary.

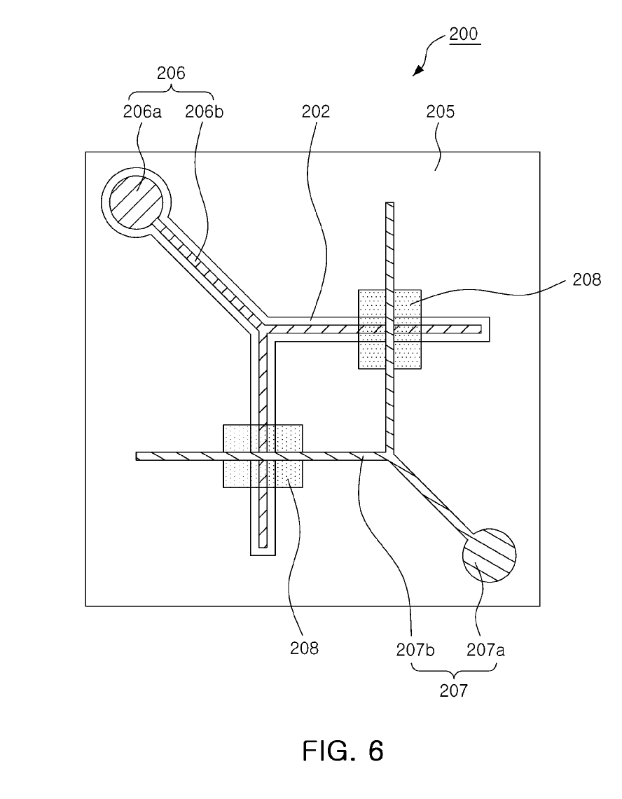

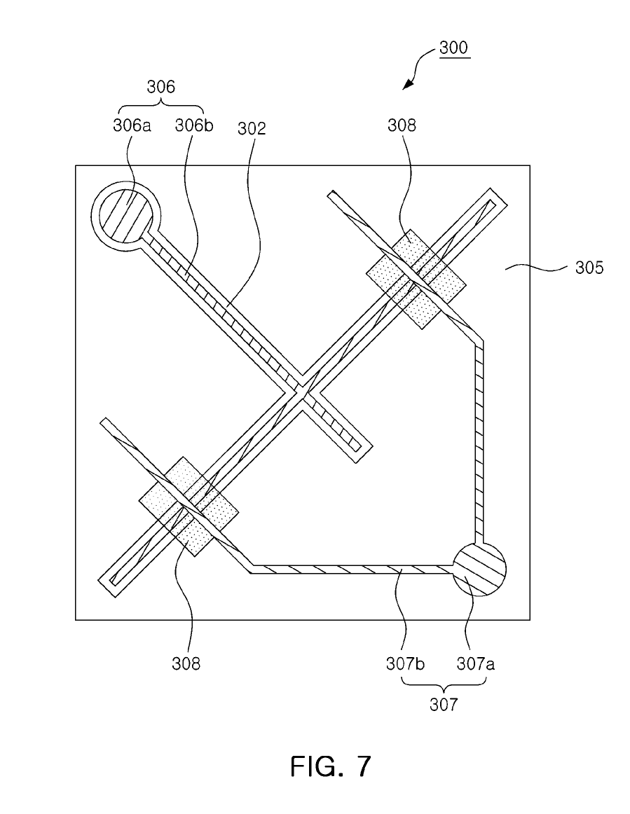

FIGS. 6 and 7 are plan views schematically showing a semiconductor light emitting device according to another embodiment of the present invention, respectively, in which examples of intersecting structures of n-type electrode and p-type electrode that may be variably applied are depicted. First, referring to FIG. 6, a semiconductor light emitting device 200 has a structure similar to that of the former embodiment, except for a specific shape of an n-type finger 206b and a p-type finger 207b. The n-type electrode 206 formed on the n-type semiconductor layer 202 includes an n-type pad 206a and the n-type finger 206b, and similarly, the p-type electrode 207 formed on a transparent electrode 205 includes a p-type pad 207a and the p-type finger 207b. In this case, the transparent electrode 205 may be omitted. The n-type pad 206a and the p-type pad 207a are disposed in the opposing corners of the light emitting surface on a light emitting surface, and the n-type finger 206b and the p-type finger 207b extend from the n-type pad 206a and the p-type pad 207a toward the opposing corners of the light emitting surface and are bifurcated in two different directions. In this case, the bifurcated portions of the n-type finger 206b and the p-type finger 207b intersect each other, and an insulating layer 208 is formed in a region in which the bifurcated portions overlap with each other.

Next, in a semiconductor light emitting device 300 according to an embodiment illustrated in FIG. 7, like the former embodiment, an n-type electrode 306 formed on an n-type semiconductor layer 302 includes an n-type pad 306a and an n-type finger 306b, and a p-type electrode 307 formed on a transparent electrode 305 includes a p-type pad 307a and a p-type finger 307b. Also, the n-type pad 306a and the p-type pad 307a are disposed in the opposing corners of the light emitting surface on a light emitting surface. The n-type finger 306b extend from the n-type pad 306a toward an opposing corner of the light emitting surface and bifurcated from the center of the light emitting surface in two directions perpendicular thereto. The p-type finger 307b extends from the p-type pad 307a toward two corners in which the n-type pad 306a and the p-type pad 307a are not formed on the light emitting surface, and bent toward the n-type pad 306a to intersect the n-type finger 306b, respectively. Also, in this case, an insulating layer 308 is formed between the n-type finger 306b and the p-type finger 307b in an area in which the n-type finger 306b and the p-type finger 307b overlap with each other.

As set forth above, in the case of the semiconductor light emitting device according to embodiments of the invention, the n-type electrode and the p-type electrode intersect each other when viewed from above the light emitting structure, reducing an area occupied by the electrodes on the light emitting surface to thus minimize a loss of light. In addition, a current dispersion effect can be improved by the insulating layer existing in a region which the n-type electrode and the p-type electrode intersect each other.

While the present invention has been shown and described in connection with the embodiments, it will be apparent to those skilled in the art that modifications and variations can be made without departing from the spirit and scope of the invention as defined by the appended claims.

What is claimed is:

1. A semiconductor light emitting device comprising:
an n-type semiconductor layer;
an active layer and a p-type semiconductor layer formed in a first region corresponding to a partial region of an upper surface of the n-type semiconductor layer;
an n-type electrode formed in a second region different from the first region on the upper surface of the n-type semiconductor layer, electrically connected to the n-type semiconductor layer, and having an n-type pad and first and second n-type fingers; and
a p-type electrode formed on the p-type semiconductor layer, electrically connected to the p-type semiconductor layer, and having a p-type pad and a p-type finger,
wherein the n-type semiconductor layer, the active layer, and the p-type semiconductor layer form a light emitting structure, and a region in which the n-type and p-type fingers intersect to overlap with each other is formed.

2. The semiconductor light emitting device of claim 1, wherein an insulating layer is interposed between the n-type finger and the p-type finger in the region in which the n-type finger and the p-type finger overlap with each other.

3. The semiconductor light emitting device of claim 2, wherein the insulating layer is formed in a region obtained by removing portions of the n-type semiconductor layer, the active layer, and the p-type semiconductor layer.

4. The semiconductor light emitting device of claim 2, wherein the insulating layer is formed in a region obtained by removing portions of the n-type semiconductor layer, the active layer, the p-type semiconductor layer, and the p-type pad.

5. The semiconductor light emitting device of claim 1, further comprising a transparent electrode formed between the p-type semiconductor layer and the p-type electrode.

6. The semiconductor light emitting device of claim 1, wherein the light emitting structure has a rectangular light emitting surface when viewed from above the p-type semiconductor layer, and the n-type electrode and the p-type electrode are disposed to have a symmetrical structure based on at least one of a horizontal line, a vertical line, and a diagonal line traversing the center of the light emitting surface.

7. The semiconductor light emitting device of claim 1, wherein the n-type finger is formed to extend in two different directions from the n-type pad, and the portions extending in the two different directions meet.

8. The semiconductor light emitting device of claim 7, wherein the p-type finger has a portion formed within a region defined by the n-type finger when viewed from above the light emitting structure.

9. The semiconductor light emitting device of claim 1, wherein the p-type finger is formed to extend in two different directions from the p-type pad, and the portions extending in the two different directions meet.

10. The semiconductor light emitting device of claim 9, wherein the n-type finger has a portion formed within a region defined by the p-type finger when viewed from above the light emitting structure.

11. The semiconductor light emitting device of claim 1, wherein the light emitting structure has a rectangular light emitting surface when viewed from above the p-type semiconductor layer, and the n-type pad and the p-type pad are disposed in opposing corners of the light emitting surface.

12. The semiconductor light emitting device of claim 11, wherein the n-type finger and the p-type finger extend from the n-type pad and the p-type pad toward the opposing corners of the light emitting surface, and are bifurcated in two different directions, and the n-type finger and the p-type finger intersect in the bifurcated regions.

13. The semiconductor light emitting device of claim 11, wherein the n-type finger extends from the n-type pad toward an opposing corner of the light emitting surface and extends from a portion positioned at the center of the light emitting surface in two directions perpendicular thereto, and the p-type finger extends from the p-type pad toward two corners in which the n-type pad and the p-type pad are not formed on the light emitting surface and is bent toward the n-type pad to intersect the n-type finger.
